(19) United States
(12) Patent Application Publication
(10) Pub. No.: US 2024/0136258 A1
(43) Pub. Date: Apr. 25, 2024

(54) COMMON LEAD FRAME, SEMICONDUCTOR DEVICE, METHOD FOR FORMING A COMMON LEAD FRAME, AND CONTROL PROGRAM

(71) Applicant: RENESAS ELECTRONICS CORPORATION, Tokyo (JP)

(72) Inventors: Junichi NITA, Tokyo (JP); Seiji HIRABAYASHI, Tokyo (JP)

(21) Appl. No.: 18/452,845

(22) Filed: Aug. 20, 2023

(30) Foreign Application Priority Data
Oct. 19, 2022 (JP) 2022-168097

(51) Int. Cl. H01L 23/495; H01L 21/48

(52) U.S. Cl. CPC H01L 23/49548; H01L 21/4828; H01L 21/4842

(57) ABSTRACT

A common lead frame can be used for both a first package and a second package and has a planar shape according to specifications of each of a first chip used in the first package and a second chip used in the second package, and a thickness of at least a part of a lead portion through which any one of a first cutting line corresponding to an outer peripheral side of the first package and a second cutting line corresponding to an outer peripheral side of the second package passes is smaller than a thickness of a lead portion through which the first cutting line and the second cutting line do not pass.

### CROSS-REFERENCE TO RELATED APPLICATIONS

The disclosure of Japanese Patent Application No. 2022-168097 filed on Oct. 20, 2022 including the specification, drawings and abstract is incorporated herein by reference in its entirety.

### BACKGROUND

The present disclosure relates to a common lead frame, a semiconductor device, a method for forming a common lead frame, and a control program, and relates to a common lead frame, a semiconductor device, a method for forming a common lead frame, and a control program suitable for suppressing an increase in cost.

There are a wide variety of packages for power MOSFETs, depending on the application. Lead frames used for these packages are individually designed and manufactured for each type of package. Therefore, a factory or the like that manufactures a plurality of types of packages needs to store a plurality of types of lead frames necessary for manufacturing a plurality of types of packages, and as a result, there is a problem that the cost for storing a plurality of types of lead frames increases.

There is disclosed a technique listed below.
[Patent Document 1] Japanese Unexamined Patent Application Publication No. 2001-203228

A solution to such a problem is disclosed in, for example, Patent Document 1. Patent Document 1 discloses a semiconductor device manufacturing method capable of manufacturing packages having different specifications with one molding die.

### SUMMARY

Other than the method disclosed in Patent Document 1, there has still been a demand for suppressing the increase in cost related to storage of a plurality of types of lead frames. Other problems and novel features will become apparent from the description of the present specification and the accompanying drawings.

According to an embodiment, a common lead frame can be used for both a first package and a second package and has a planar shape according to specifications of each of a first chip used in the first package and a second chip used in the second package, and a thickness of at least a part of a lead portion through which any one of a first cutting line corresponding to an outer peripheral side of the first package and a second cutting line corresponding to an outer peripheral side of the second package passes is smaller than a thickness of a lead portion through which the first cutting line and the second cutting line do not pass.

According to an embodiment, a method for forming a common lead frame includes using a computer to form a planar shape of a common lead frame that can be used for both a first package and a second package, based on specifications of each of a first chip used in the first package and a second chip used in the second package, and make a thickness of at least a part of a lead portion through which any one of a first cutting line corresponding to an outer peripheral side of the first package and a second cutting line corresponding to an outer peripheral side of the second package passes smaller than a thickness of a lead portion through which the first cutting line and the second cutting line do not pass in the common lead frame.

According to an embodiment, a control program causes a computer to execute processing of forming a planar shape of a common lead frame that can be used for both a first package and a second package, based on specifications of each of a first chip used in the first package and a second chip used in the second package, and making a thickness of at least a part of a lead portion through which any one of a first cutting line corresponding to an outer peripheral side of the first package and a second cutting line corresponding to an outer peripheral side of the second package passes smaller than a thickness of a lead portion through which the first cutting line and the second cutting line do not pass in the common lead frame.

The present disclosure can provide a common lead frame, a semiconductor device, a method for forming a common lead frame, and a control program capable of suppressing the increase in cost.

### BRIEF DESCRIPTION OF THE DRAWINGS

FIG. 1 is a flowchart illustrating a method for forming a common lead frame according to a first embodiment.

FIG. 2 is a diagram illustrating a planar shape of a first lead frame dedicated to a first package and a planar shape of a second lead frame dedicated to a second package.

FIG. 3 is a diagram illustrating a planar shape of an intermediate lead frame in which the first and second lead frames are superimposed on each other and a planar shape of the common lead frame according to the first embodiment that can be used for each of the first and second packages.

FIG. 4 is a diagram illustrating the planar shape of the common lead frame according to the first embodiment.

FIG. 5 is a diagram illustrating a planar shape of a plurality of common lead frames integrally formed in a matrix.

FIG. 6 is a perspective view illustrating a part of the common lead frame according to the first embodiment.

FIG. 7 is a diagram illustrating the planar shape of the common lead frame illustrated in FIG. 4 and a planar shape of a third lead frame dedicated to a third package.

FIG. 8 is a diagram illustrating a planar shape of an intermediate lead frame in which the common lead frame illustrated in FIG. 4 and the third lead frame are superimposed on each other, and a planar shape of a common lead frame according to a second embodiment that can be used for each of the first to third packages.

FIG. 9 is a diagram illustrating the planar shape of the common lead frame according to the second embodiment.

FIG. 10 is a diagram illustrating a planar shape of a plurality of common lead frames integrally formed in a matrix.

FIG. 11 is a diagram illustrating the planar shape of the first lead frame dedicated to the first package and a planar shape of a fourth lead frame dedicated to a fourth package.

FIG. 12 is a diagram illustrating a planar shape of an intermediate lead frame in which the first lead frame and the fourth lead frame are superimposed on each other and a planar shape of a common lead frame according to a third embodiment that can be used for each of the first and fourth packages.

FIG. 13 is a diagram illustrating the planar shape of the common lead frame according to the third embodiment.

FIG. 14 is a diagram illustrating a planar shape of a plurality of common lead frames integrally formed in a matrix.

### DETAILED DESCRIPTION

Hereinafter, embodiments will be described with reference to the drawings. Since the drawings are simplified, the technical scope of the embodiments should not be narrowly interpreted based on the description of the drawings. In addition, the same elements are denoted by the same reference signs, and redundant description will be omitted.

In the following description, the invention will be described in a plurality of sections or embodiments when required as a matter of convenience. However, these sections or embodiments are not irrelevant to each other unless otherwise stated, and the one relates to the entire or a part of the other as a modification, details, or a supplementary explanation thereof. Also, in the embodiments described below, when mentioning the number of elements (including number of pieces, values, amount, range, and the like), the number of the elements is not limited to a specific number unless otherwise stated or except the case where the number is apparently limited to a specific number in principle, and the number larger or smaller than the specified number is also applicable.

Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

### First Embodiment

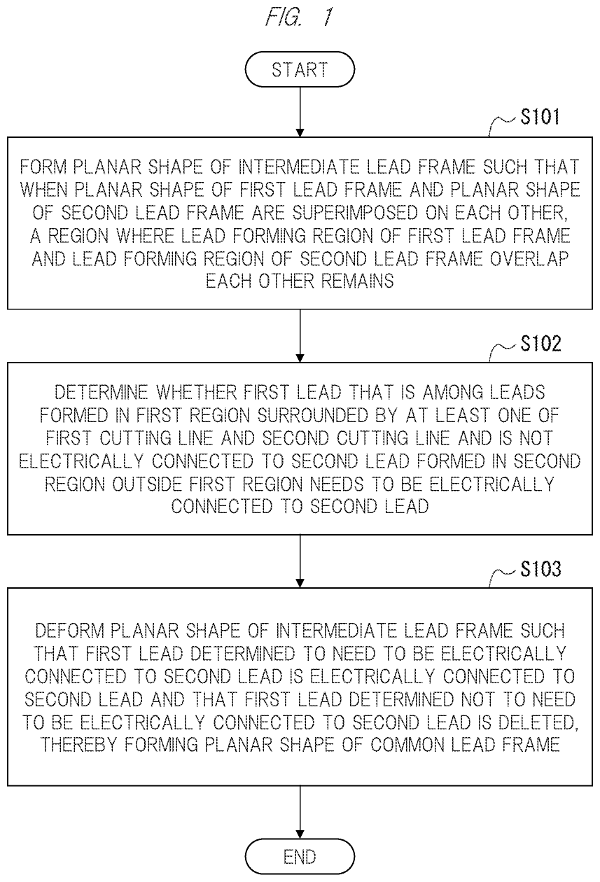

A method for forming a common lead frame LF40 according to a first embodiment will be described with reference to FIGS. 1 to 4. FIG. 1 is a flowchart illustrating the method for forming the common lead frame LF40 according to the first embodiment. The common lead frame LF40 is a lead frame that can be used for both of two types of packages (semiconductor devices) PKG1 and PKG2 having different sizes.

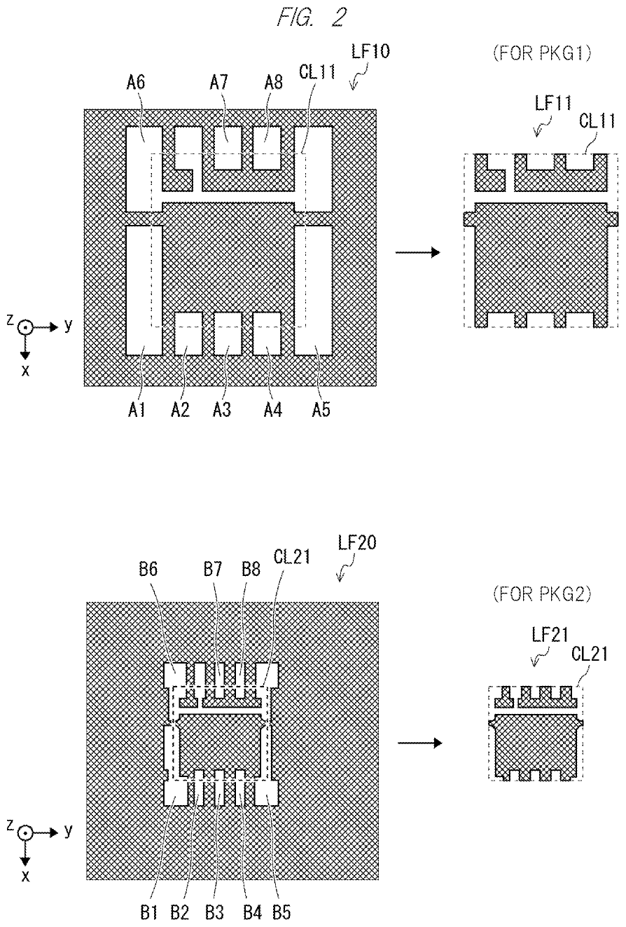

FIG. 2 is a diagram illustrating a planar shape of a lead frame LF10 dedicated to the first package PKG1 and a planar shape of a lead frame LF20 dedicated to the second package PKG2. FIG. 2 also illustrates a planar shape of a lead frame LF11 cut out from the lead frame LF10 and a planar shape of a lead frame LF21 cut out from the lead frame LF20.

In the present embodiment, a case will be described in which after a designing device or the like designs the layout of the common lead frame LF40 with reference to the lead frame LF10 dedicated to the first package PKG1 and the lead frame LF20 dedicated to the second package PKG2, a manufacturing device or the like manufactures the common lead frame LF40 having the designed layout.

First, the lead frame LF10 has a planar shape according to specifications of a semiconductor chip CHP1 mounted on the first package PKG1. Specifically, spatial regions A1 to A8 are formed in the lead frame LF10. In the lead frame LF10, the spatial regions A1 to A8 are regions where no leads are formed, and a region other than the spatial regions A1 to A8 is a region (lead forming region) where leads are formed. Depending on the lead forming region, a die pad on which the semiconductor chip CHP1 is disposed is formed, a lead (inner lead or outer lead) for electrically connecting the semiconductor chip CHP1 inside the package to the outside of the package, or the like is formed.

The lead frame LF11 is formed for each of first packages PKG1 by performing positioning of the semiconductor chip CHP1, die bonding, wire bonding, resin sealing, and the like on a plurality of lead frames LF10 integrally formed in a matrix, and then cutting each of the lead frames LF10 along a cutting line CL11.

In addition, the lead frame LF20 has a planar shape according to specifications of a semiconductor chip CHP2 mounted on the second package PKG2. Specifically, spatial regions B1 to B8 are formed in the lead frame LF20. In the lead frame LF20, the spatial regions B1 to B8 are regions where no leads are formed, and a region other than the spatial regions B1 to B8 is a region (lead forming region) where leads are formed. Depending on the lead forming region, a die pad on which the semiconductor chip CHP2 is disposed is formed, a lead (inner lead or outer lead) for electrically connecting the semiconductor chip CHP2 inside the package to the outside of the package, or the like is formed.

The lead frame LF21 is formed for each of second packages PKG2 by performing positioning of the semiconductor chip CHP2, die bonding, wire bonding, resin sealing, and the like on a plurality of lead frames LF20 integrally formed in a matrix, and then cutting each of the lead frames LF20 along a cutting line CL21.

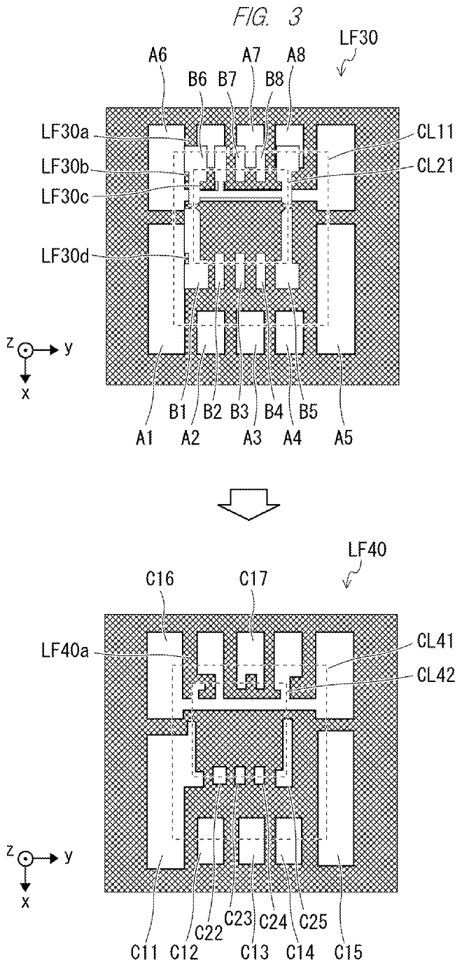

FIG. 3 is a diagram illustrating a planar shape of an intermediate lead frame LF30 in which the lead frames LF10 and LF20 are superimposed on each other and a planar shape of the common lead frame LF40 according to the first embodiment that can be used for each of the first package PKG1 and the second package PKG2.

As illustrated in FIG. 3, in the method for forming the common lead frame LF40, first, the planar shape of the intermediate lead frame LF30 is formed such that, when the planar shape of the lead frame LF10 and the planar shape of the lead frame LF20 are superimposed on each other, a region where the lead forming region of the lead frame LF10 and the lead forming region of the lead frame LF20 overlap each other remains (step S101 in FIG. 1).

Thereafter, in the method for forming the common lead frame LF40, it is determined whether a lead (first lead) that is among leads formed in a region (first region) surrounded by at least one of the cutting lines CL11 and CL21 and is not electrically connected to a lead (second lead) formed in a region (second region) outside the first region in the intermediate lead frame LF30 needs to be electrically connected to the second lead, based on the specifications of the semiconductor chips CHP1 and CHP2 (step S102 in FIG. 1).

In the example of FIG. 3, since the first package PKG1 is larger than the second package PKG2, a region surrounded by the cutting line CL11 includes a region surrounded by the cutting line CL21. In this case, leads (first leads) LF30b, LF30c, and LF30d formed in the region (first region) surrounded by the cutting line CL11 are not electrically connected to the lead (second lead) formed in the region (second region) outside the region surrounded by the cutting line CL11. That is, the leads LF30b, LF30c, and LF30d are in a floating state.

Thereafter, in the method for forming the common lead frame LF40, the planar shape of the intermediate lead frame LF30 is deformed such that the first lead determined to need to be electrically connected to the second lead is electrically connected to the second lead and that the first lead determined not to need to be electrically connected to the second lead is deleted so as to form the planar shape of the common lead frame LF40 (step S103 in FIG. 1).

In the example of FIG. 3, among the leads LF30b, LF30c, and LF30d that are the first leads, the leads LF30b and LF30c are determined to be necessary for the semiconductor chips CHP1 and CHP2, and the lead LF30d is determined to be unnecessary for the semiconductor chips CHP1 and CHP2. Therefore, the planar shape of the intermediate lead frame LF30 is deformed such that the leads LF30b and LF30c are electrically connected to a lead LF30a that is the second lead and that the lead LF30d is deleted. As a result, the planar shape of the common lead frame LF40 that can be used for both the first package PKG1 and the second package PKG2 is formed. In the common lead frame LF40, the leads LF30b and LF30c and the lead LF30a are integrally formed as a lead LF40a.

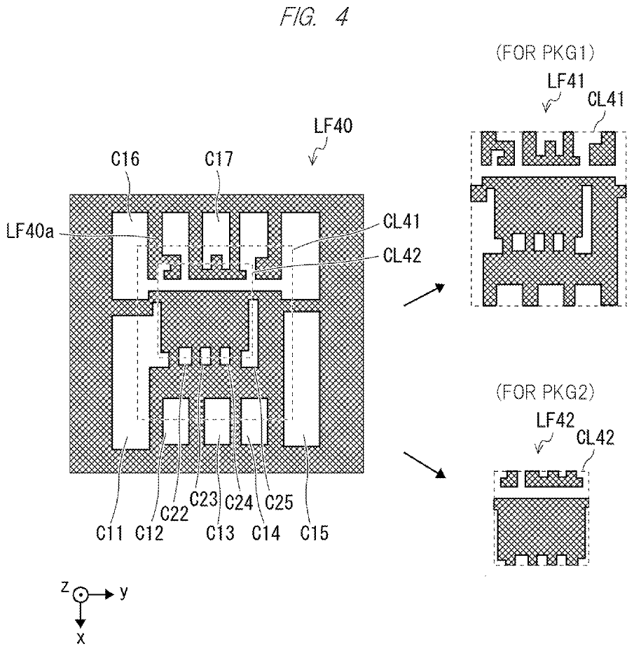

FIG. 4 is a diagram illustrating the planar shape of the common lead frame LF40 according to the first embodiment. FIG. 4 also illustrates planar shapes of lead frames LF41 and LF42 cut out from the common lead frame LF40. The lead frame LF41 corresponds to the lead frame LF11, and the lead frame LF42 corresponds to the lead frame LF21.

The common lead frame LF40 has a planar shape according to the specifications of each of the semiconductor chip CHP1 mounted on the first package PKG1 and the semiconductor chip CHP2 mounted on the second package PKG2. Specifically, spatial regions C11 to C17 and C22 to C25 are formed in the common lead frame LF40. The spatial region C11 corresponds to the spatial regions A1 and B2, the spatial region C12 corresponds to the spatial region A2, the spatial region C13 corresponds to the spatial region A3, the spatial region C14 corresponds to the spatial region A4, the spatial region C15 corresponds to the spatial region A5, the spatial region C16 corresponds to the spatial regions A6, A8, and B6, the spatial region C17 corresponds to the spatial regions A7, B7, and B8, the spatial region C22 corresponds to the spatial region B2, the spatial region C23 corresponds to the spatial region B3, the spatial region C24 corresponds to the spatial region B4, and the spatial region C25 corresponds to the spatial region B5.

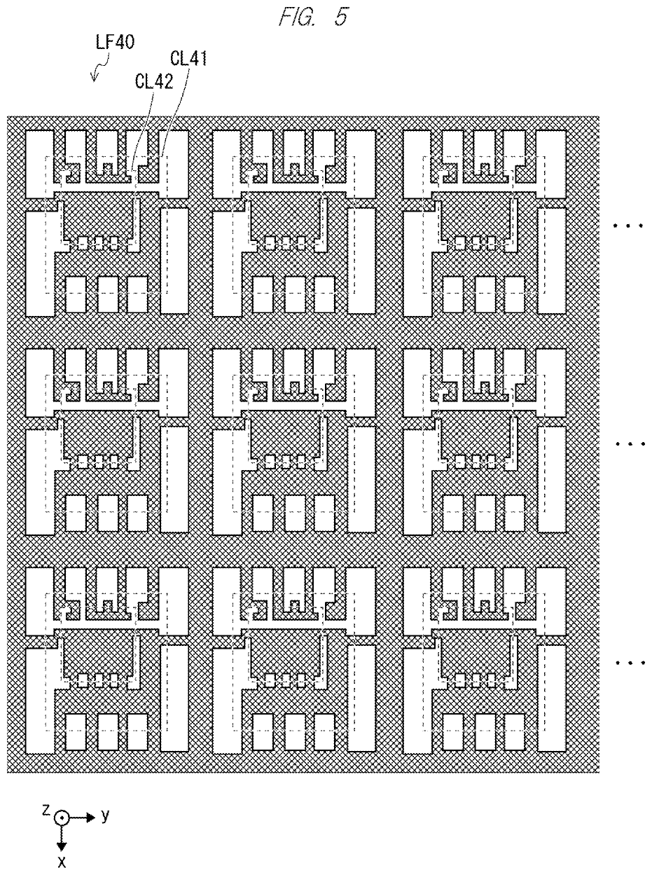

FIG. 5 is a diagram illustrating a planar shape of a plurality of common lead frames LF40 integrally formed in a matrix. The lead frame LF41 is formed for each of the first packages PKG1 by performing positioning of the semiconductor chip CHP1, die bonding, wire bonding, resin sealing, and the like on the plurality of common lead frames LF40 integrally formed in the matrix, and then cutting each of the common lead frames LF40 along a cutting line CL41. The lead frame LF42 is formed for each of the second packages PKG2 by performing positioning of the semiconductor chip CHP2, die bonding, wire bonding, resin sealing, and the like on the plurality of common lead frames LF40 integrally formed in the matrix, and then cutting each of the common lead frames LF40 along a cutting line CL42.

In the present embodiment, a case where the common lead frame LF40 is cut along the cutting line CL41 or the cutting line CL42 by dicing will be described as an example, but the present invention is not limited thereto. For example, the common lead frame LF40 may be cut along the cutting line CL41 or the cutting line CL42 by etching, pressing, or the like. The same applies to cutting of other lead frames described below.

As described above, the common lead frame LF40 according to the present embodiment can be used for both of two types of packages PKG1 and PKG2 having different sizes. As a result, for example, a factory or the like that manufactures a plurality of types of packages including the two types of packages PKG1 and PKG2 can reduce the types of lead frames to be stored, and thus, it is possible to suppress an increase in cost related to storage of the plurality of types of packages.

In the common lead frame LF40, a thickness (length in the z-axis direction) of at least a part of a lead portion through which any one of the cutting lines CL41 and CL42 passes is preferably smaller than a thickness of a lead portion through which the cutting lines CL41 and CL42 do not pass. In the common lead frame LF40, a through hole (spatial region) is preferably formed in at least a part of a lead portion through which any one of the cutting lines CL41 and CL42 passes. This facilitates cutting of the common lead frame LF40 along the cutting lines CL41 and CL42.

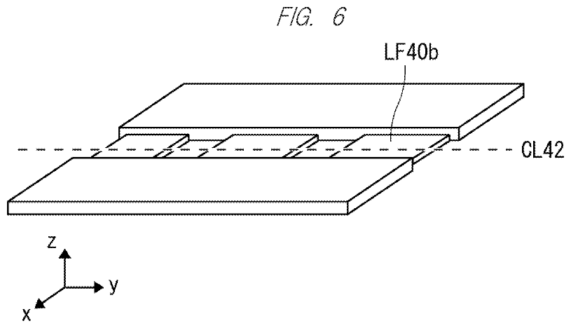

FIG. 6 is a perspective view illustrating a part of the common lead frame LF40. In an example illustrated in FIG. 6, in the common lead frame LF40, a thickness (length in the z-axis direction) of a part LF40b of a lead portion through which the cutting line CL42 passes is smaller than thicknesses of the other lead portions. A through hole (spatial region) is formed in a part of the lead portion through which the cutting line CL42 passes. This facilitates cutting of the common lead frame LF40 along the cutting line CL42.

### Second Embodiment

A method for forming a common lead frame LF70 according to a second embodiment will be described with reference to FIGS. 1 and 7 to 10. The common lead frame LF70 is a lead frame that can be used for any of three types of packages (semiconductor devices) PKG1 to PKG3. A method for forming the common lead frame LF70 is basically similar to the method for forming the common lead frame LF40.

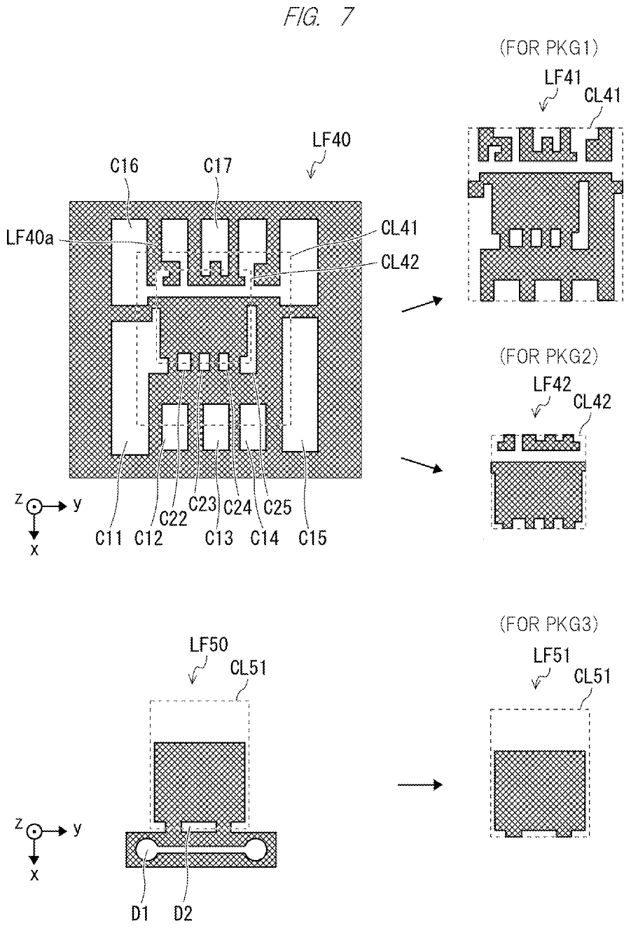

FIG. 7 is a diagram illustrating the planar shape of the common lead frame LF40 and a planar shape of a lead frame LF50 dedicated to the third package PKG3. FIG. 7 also illustrates the planar shapes of the lead frames LF41 and LF42 cut out from the common lead frame LF40 and a planar shape of a lead frame LF51 cut out from the lead frame LF50.

In the present embodiment, a case will be described in which after a designing device or the like designs the layout of the common lead frame LF70 with reference to the lead frame LF10 dedicated to the first package PKG1, the lead frame LF20 dedicated to the second package PKG2, and the lead frame LF50 dedicated to the third package PKG3, a manufacturing device or the like manufactures the common lead frame LF70 having the designed layout.

In addition, the lead frame LF50 has a planar shape according to specifications of a semiconductor chip CHP3 mounted on the third package PKG3. Specifically, spatial regions D1 and D2 are formed in the lead frame LF50. In the lead frame LF50, the spatial regions D1 and D2 are regions where no leads are formed, and a region other than the spatial regions D1 and D2 is a region (lead forming region) where leads are formed. Depending on the lead forming region, a die pad on which the semiconductor chip CHP3 is disposed is formed, a lead for electrically connecting the semiconductor chip CHP3 inside the package to the outside of the package, or the like is formed. Alternatively, a clip that electrically connects the semiconductor chip CHP3 inside the package to the outside of the package may be further disposed.

The lead frame LF51 is formed for each of third packages PKG3 by performing positioning of the semiconductor chip CHP3, die bonding, wire bonding, resin sealing, and the like on a plurality of lead frames LF50 integrally formed in a matrix, and then cutting each of the lead frames LF50 along a cutting line CL51.

Since the common lead frame LF40 is as described above, the description thereof will be omitted.

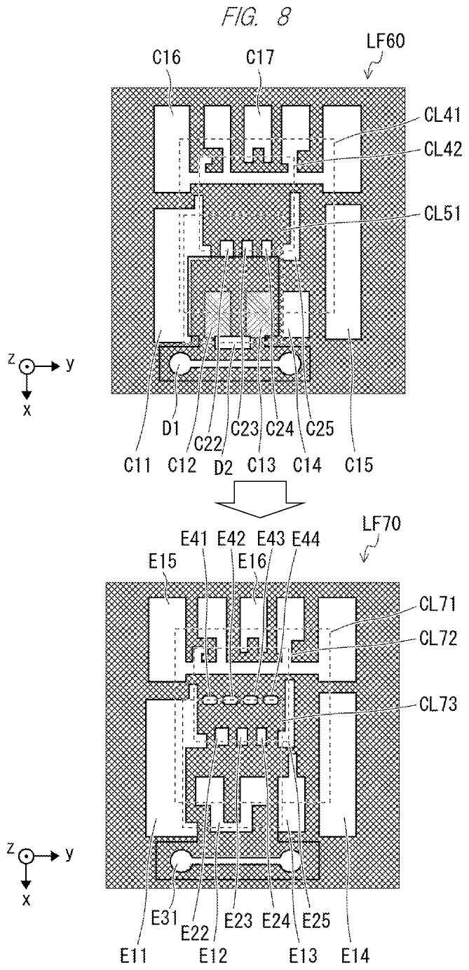

FIG. 8 is a diagram illustrating a planar shape of an intermediate lead frame LF60 in which the lead frames LF40 and LF50 are superimposed on each other, and a planar shape of the common lead frame LF70 according to the second embodiment that can be used for each of the first package PKG1, the second package PKG2, and the third package PKG3.

As illustrated in FIG. 8, in the method for forming the common lead frame LF70, first, the planar shape of the intermediate lead frame LF60 is formed such that, when the planar shape of the common lead frame LF40 and the planar shape of the lead frame LF50 are superimposed on each other, a region where the lead forming region of the common lead frame LF40 and the lead forming region of the lead frame LF50 overlap each other remains (step S101 in FIG. 1).

Thereafter, in the method for forming the common lead frame LF70, it is determined whether a lead (first lead) that is among leads formed in a region (first region) surrounded by at least one of the cutting lines CL41, CL42, and CL51 and is not electrically connected to a lead (second lead) formed in a region (second region) outside the first region in the intermediate lead frame LF60 needs to be electrically connected to the second lead, based on the specifications of the semiconductor chips CHP1 to CHP3 (step S102 in FIG. 1).

In the example of FIG. 8, a region surrounded by the cutting line CL41 (CL42) and a region surrounded by the cutting line CL51 partially overlap each other. In this case, in the example illustrated in FIG. 8, among the leads formed in the first region, there is no lead (first lead) that is not electrically connected to the lead (second lead) formed in the second region. Therefore, the planar shape of the common lead frame LF70 is formed without electrical connection between the first lead and the second lead or deletion of the first lead (step S103 in FIG. 1).

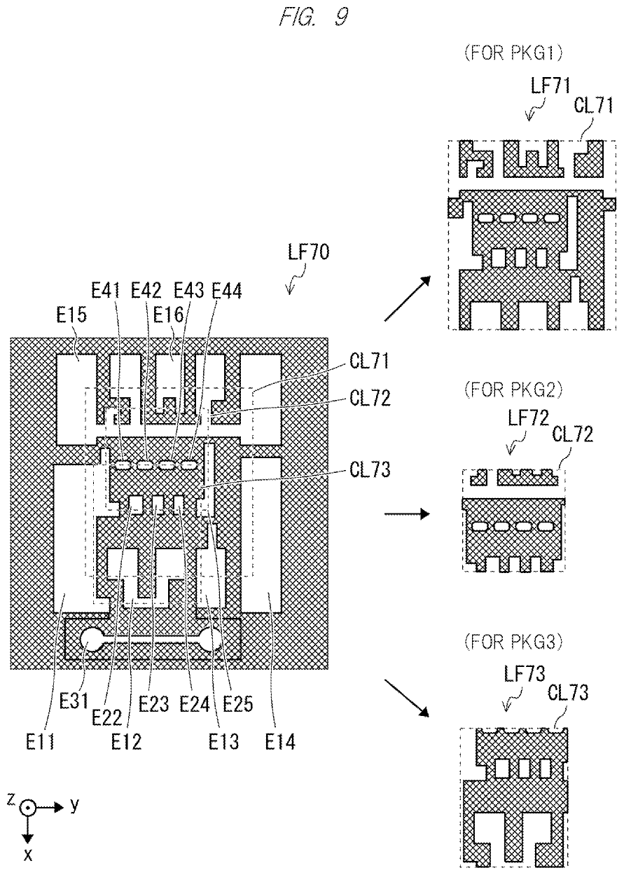

FIG. 9 is a diagram illustrating the planar shape of the common lead frame LF70 according to the second embodiment. FIG. 9 also illustrates planar shapes of lead frames LF71 to LF73 cut out from the common lead frame LF70. The lead frame LF71 corresponds to the lead frame LF41, the lead frame LF72 corresponds to the lead frame LF42, and the lead frame LF73 corresponds to the lead frame LF51.

The common lead frame LF70 has a planar shape according to the specifications of each of the semiconductor chips CHP1 to CHP3. Specifically, spatial regions E11 to E16, E22 to E25, E31, and E41 to E44 are formed in the common lead frame LF70. The spatial region E11 corresponds to the spatial region C11, the spatial region E12 corresponds to the spatial regions C12, C13, and D2, the spatial regions E13 to E16 correspond to the spatial regions C14 to C17, respectively, the spatial regions E22 to E25 correspond to the spatial regions C22 to C25, respectively, and the spatial region E31 corresponds to the spatial region D1. The spatial regions E41 to E44 are newly formed.

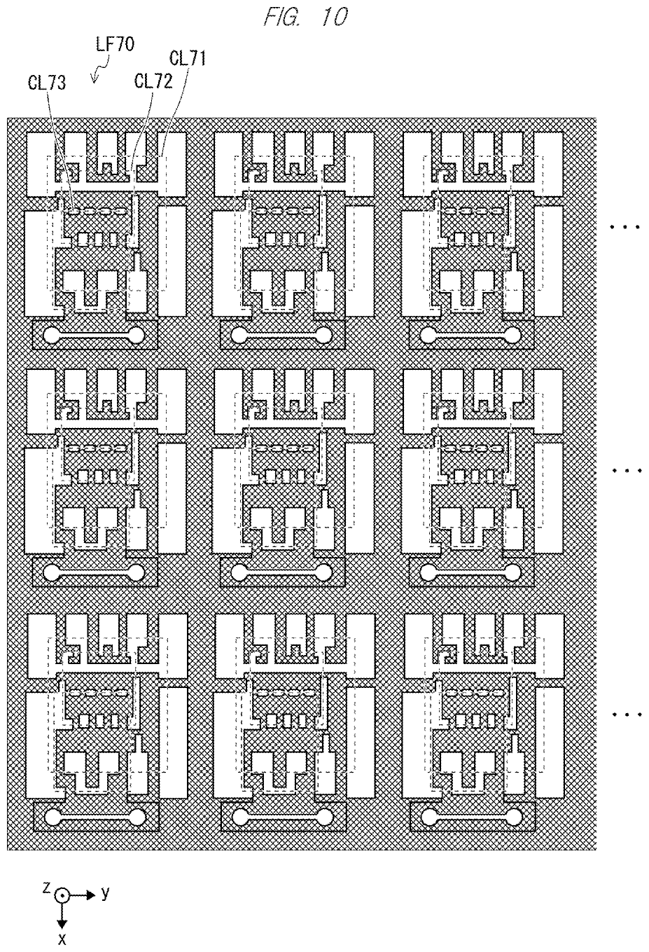

FIG. 10 is a diagram illustrating a planar shape of a plurality of common lead frames LF70 integrally formed in a matrix. The lead frame LF71 is formed for each of first packages PKG1 by performing positioning of the semiconductor chip CHP1, die bonding, wire bonding, resin sealing, and the like on the plurality of common lead frames LF70 integrally formed in the matrix, and then cutting each of the common lead frames LF70 along a cutting line CL71. The lead frame LF72 is formed for each of second packages PKG2 by performing positioning of the semiconductor chip CHP2, die bonding, wire bonding, resin sealing, and the like on the plurality of common lead frames LF70 integrally formed in the matrix, and then cutting each of the common lead frames LF70 along a cutting line CL72. The lead frame LF73 is formed for each of the third packages PKG3 by performing positioning of the semiconductor chip CHP3, die bonding, wire bonding, resin sealing, and the like on the plurality of common lead frames LF70 integrally formed in the matrix, and then cutting each of the common lead frames LF70 along a cutting line CL73.

As described above, the common lead frame LF70 according to the present embodiment can be used for any of the three types of packages PKG1 to PKG 3. As a result, for example, a factory or the like that manufactures a plurality of types of packages including the three types of packages PKG1 to PKG3 can reduce the types of lead frames to be stored, and thus, it is possible to suppress an increase in cost related to storage of the plurality of types of packages.

In the common lead frame LF70, the spatial regions E41 to E44 are formed in a part of a lead portion through which the cutting line CL73 passes. This facilitates cutting of the common lead frame LF70 along the cutting line CL73.

### Third Embodiment

A method for forming a common lead frame LF100 according to a third embodiment will be described with reference to FIGS. 1 and 11 to 14. The common lead frame LF100 is a lead frame that can be used for both of two types of packages (semiconductor devices) PKG1 and PKG 4 having similar sizes. A method for forming the common lead frame LF100 is basically similar to the method for forming the common lead frame LF40.

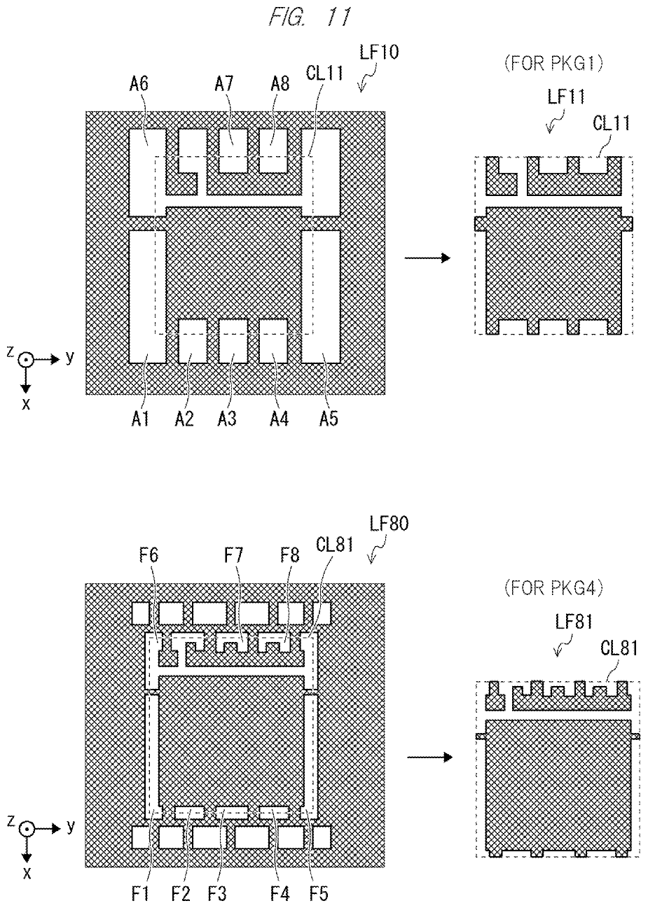

FIG. 11 is a diagram illustrating the planar shape of the lead frame LF10 and a planar shape of a lead frame LF80 dedicated to the fourth package PKG4. FIG. 11 also illustrates the planar shape of the lead frame LF11 cut out from the lead frame LF10 and a planar shape of a lead frame LF81 cut out from the lead frame LF80.

In the present embodiment, a case will be described in which after a designing device or the like designs the layout of the common lead frame LF70 with reference to the lead frame LF10 dedicated to the first package PKG1 and the lead frame LF80 dedicated to the fourth package PKG4, a manufacturing device or the like manufactures the common lead frame LF70 having the designed layout.

The lead frame LF80 has a planar shape according to specifications of a semiconductor chip CHP4 mounted on the fourth package PKG4. Specifically, spatial regions F1 to F8 are formed in the lead frame LF80. In the lead frame LF80, the spatial regions F1 to F8 are regions where no leads are formed, and a region other than the spatial regions F1 to F8 is a region (lead forming region) where leads are formed. Depending on the lead forming region, a die pad on which the semiconductor chip CHP4 is disposed is formed, a lead (inner lead or outer lead) for electrically connecting the semiconductor chip CHP4 inside the package to the outside of the package, or the like is formed.

The lead frame LF81 is formed for each of fourth packages PKG4 by performing positioning of the semiconductor chip CHP4, die bonding, wire bonding, resin sealing, and the like on a plurality of lead frames LF80 integrally formed in a matrix, and then cutting each of the lead frames LF80 along a cutting line CL81.

Since the lead frame LF10 is as described above, the description thereof will be omitted.

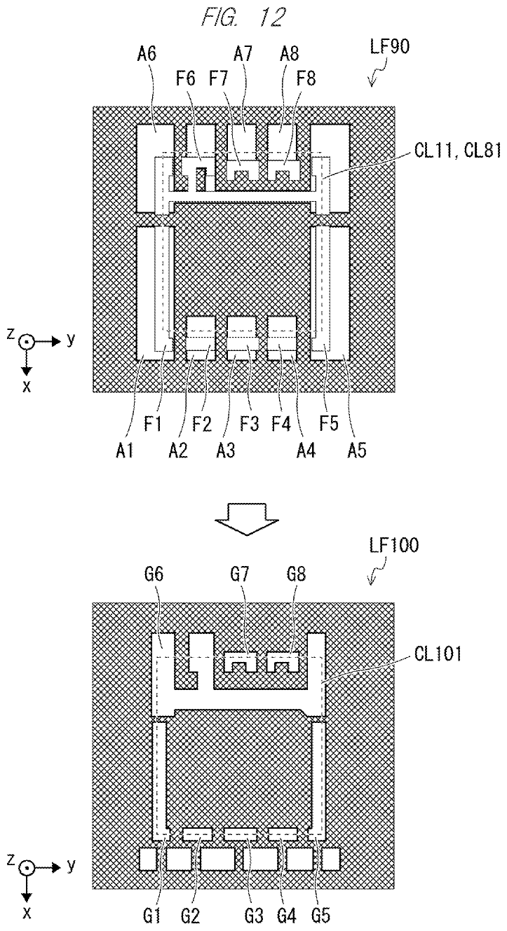

FIG. 12 is a diagram illustrating a planar shape of an intermediate lead frame LF90 in which the lead frames LF10 and LF80 are superimposed on each other and a planar shape of the common lead frame LF100 according to the third embodiment that can be used for each of the first package PKG1 and the fourth package PKG4.

As illustrated in FIG. 12, in the method for forming the common lead frame LF100, first, the planar shape of the intermediate lead frame LF90 is formed such that, when the planar shape of the lead frame LF10 and the planar shape of the lead frame LF80 are superimposed on each other, a region where the lead forming region of the lead frame LF10 and the lead forming region of the lead frame LF80 overlap each other remains (step S101 in FIG. 1).

Thereafter, in the method for forming the common lead frame LF100, it is determined whether a lead (first lead) that is among leads formed in a region (first region) surrounded by at least one of the cutting lines CL11 and CL81 and is not electrically connected to a lead (second lead) formed in a region (second region) outside the first region in the intermediate lead frame LF90 needs to be electrically connected to the second lead, based on the specifications of the semiconductor chips CHP1 and CHP4 (step S102 in FIG. 1).

In the example illustrated in FIG. 12, among the leads formed in the first region, there is no lead (first lead) that is not electrically connected to the lead (second lead) formed in the second region. Therefore, the planar shape of the common lead frame LF100 is formed without electrical connection between the first lead and the second lead or deletion of the first lead (step S103 in FIG. 1).

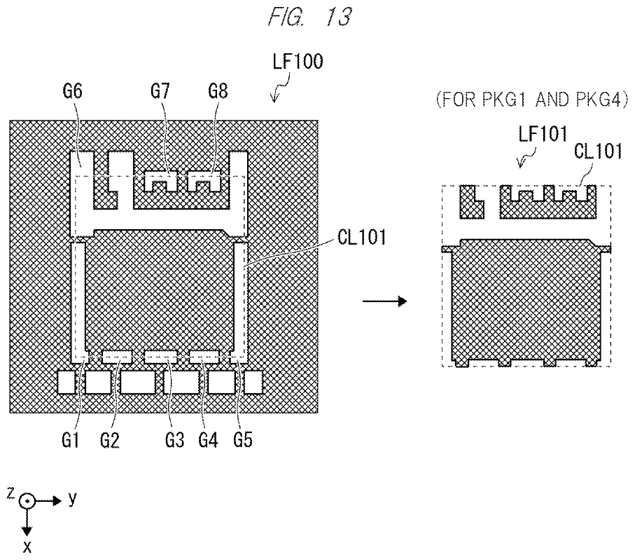

FIG. 13 is a diagram illustrating the planar shape of the common lead frame LF100 according to the third embodiment. FIG. 13 also illustrates a planar shape of a lead frame LF101 cut out from the common lead frame LF100. The lead frame LF101 corresponds to the lead frames LF11 and LF81.

The common lead frame LF100 has a planar shape according to the specifications of each of the semiconductor chips CHP1 to CHP4. Specifically, spatial regions G1 to G8 are formed in the common lead frame LF100. The spatial region G1 corresponds to the spatial regions A1 and F1, the spatial region G2 corresponds to the spatial regions A2 and F2, the spatial region G3 corresponds to the spatial regions A3 and F3, the spatial region G4 corresponds to the spatial regions A4 and F4, the spatial region G5 corresponds to the spatial regions A5 and F5, the spatial region G6 corresponds to the spatial regions A6 and F6, the spatial region G7 corresponds to the spatial regions A7 and F7, and the spatial region G8 corresponds to the spatial regions A8 and F8.

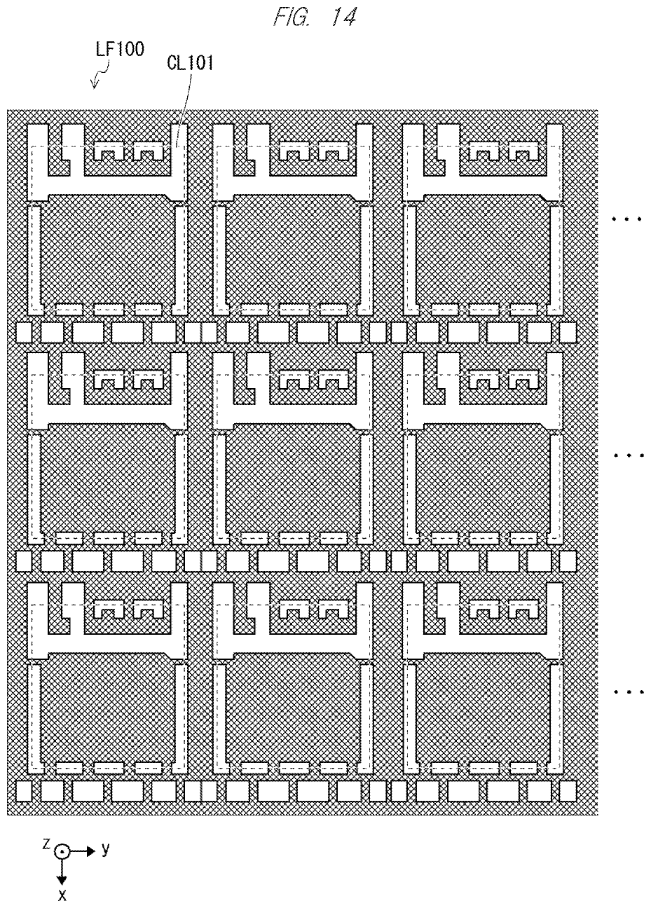

FIG. 14 is a diagram illustrating a planar shape of a plurality of common lead frames LF100 integrally formed in a matrix. The lead frame LF101 is formed for each of the first packages PKG1 by performing positioning of the semiconductor chip CHP1, die bonding, wire bonding, resin sealing, and the like on the plurality of common lead frames LF100 integrally formed in the matrix, and then cutting each of the common lead frames LF100 along a cutting line CL101. Alternatively, the lead frame LF101 is formed for each of the fourth packages PKG4 by performing positioning of the semiconductor chip CHP2, die bonding, wire bonding, resin sealing, and the like on the plurality of common lead frames LF100 integrally formed in the matrix, and then cutting each of the common lead frames LF100 along the cutting line CL101.

As described above, the common lead frame LF100 according to the present embodiment can be used for both of two types of packages PKG1 and PKG4 having similar sizes. As a result, for example, a factory or the like that manufactures a plurality of types of packages including the two types of packages PKG1 and PKG4 can reduce the types of lead frames to be stored, and thus, it is possible to suppress an increase in cost related to storage of the plurality of types of packages.

Although the invention made by the present inventors has been specifically described based on the embodiments, the present invention is not limited to the embodiments described above, and it goes without saying that various modifications can be made without departing from the gist of the present invention.

Furthermore, the present disclosure can be implemented by causing a central processing unit (CPU) to execute a computer program for part or all of the lead frame forming processing.

The above-described program includes a command group (or software code) for causing a computer to perform one or more of the functions described in the embodiments when being read by the computer. The program may be stored in a non-transitory computer-readable medium or a tangible storage medium. By way of example, and not limitation, the computer-readable medium or the tangible storage medium includes a random-access memory (RAM), a read-only memory (ROM), a flash memory, a solid-state drive (SSD), or other memory technology, a CD-ROM, a digital versatile disc (DVD), a Blu-ray (registered trademark) disc, or other optical disc storage, or a magnetic cassette, magnetic tape, magnetic disk storage, or another magnetic storage device. The program may be transmitted on a transitory computer readable medium or a communication medium. By way of example, and not limitation, the transitory computer-readable medium or the communication medium includes an electrical, optical, or acoustic propagated signal, or a propagated signal in another form.

Some or all of the above embodiments may be described as the following supplementary notes, but are not limited to the following.

(Supplementary Note 1)

A method for forming a common lead frame, the method including causing a computer to:
form a planar shape of an intermediate lead frame such that, when a planar shape of a first lead frame used in a first package and a planar shape of a second lead frame used in a second package are superimposed on each other, a region where a lead forming region of the first lead frame and a lead forming region of the second lead frame overlap each other remains;
determine whether a first lead that is among leads formed in a first region surrounded by at least one of a first cutting line corresponding to an outer peripheral side of the first package and a second cutting line corresponding to an outer peripheral side of the second package and is not electrically connected to a second lead formed in a second region outside the first region in the intermediate lead frame needs to be electrically connected to the second lead, based on specifications of a first chip used in the first package and a second chip used in the second package; and
deform the planar shape of the intermediate lead frame such that the first lead determined to need to be electrically connected to the second lead is electrically connected to the second lead and that the first lead determined not to need to be electrically connected to the second lead is deleted, thereby forming a planar shape of a common lead frame that can be used for both the first package and the second package.

(Supplementary Note 2)

The method for forming a common lead frame according to Supplementary Note 1, the method including:
making a thickness of at least a part of a lead portion through which any one of the first cutting line and the second cutting line passes smaller than a thickness of a lead portion through which the first cutting line and the second cutting line do not pass in the intermediate lead frame.

(Supplementary Note 3)

The method for forming a common lead frame according to Supplementary Note 1, the method including:
forming a through hole in at least a part of a lead portion through which any one of the first cutting line and the second cutting line passes in the intermediate lead frame.

(Supplementary Note 4)

The method for forming a common lead frame according to Supplementary Note 1, the method including:
forming a planar shape of the intermediate lead frame such that, when the planar shape of the first lead frame, the planar shape of the second lead frame, and a planar shape of a third lead frame used for a third package are superimposed, a region in which the lead forming region of the first lead frame, the lead forming region of the second lead frame, and a lead forming region of the third lead frame overlap remains;
determining whether the first lead that is among leads formed in the first region surrounded by at least one of the first cutting line, the second cutting line, and a third cutting line corresponding to an outer peripheral side of the third package and is not electrically connected to the second lead formed in the second region outside the first region in the intermediate lead frame needs to be electrically connected to the second lead, based on specifications of each of the first chip, the second chip, and a third chip used in the third package; and
deforming a planar shape of the intermediate lead frame such that the first lead determined to need to be electrically connected to the second lead is electrically connected to the second lead and that the first lead determined not to need to be electrically connected to the second lead is deleted so as to form a planar shape of a common lead frame that can be used for any of the first package, the second package, and the third package.

(Supplementary Note 5)

The method for forming a common lead frame according to Supplementary Note 4, the method including:
making a thickness of at least a part of a lead portion through which any one of the first cutting line, the second cutting line, and the third cutting line passes smaller than a thickness of a lead portion through which the first cutting line, the second cutting line, and the third cutting line do not pass in the intermediate lead frame.

(Supplementary Note 6)

The method for forming a common lead frame according to Supplementary Note 4, the method including:
forming a through hole in at least a part of a lead portion through which any one of the first cutting line, the second cutting line, and the third cutting line passes in the intermediate lead frame.

(Supplementary Note 7)

A control program for causing a computer to execute processing of:
forming a planar shape of an intermediate lead frame such that, when a planar shape of a first lead frame used for a first package and a planar shape of a second lead frame used for a second package are superimposed on each other, a region where a lead forming region of the first lead frame and a lead forming region of the second lead frame overlap each other remains;
determining whether a first lead that is among leads formed in a first region surrounded by at least one of a first cutting line corresponding to an outer peripheral side of the first package and a second cutting line corresponding to an outer peripheral side of the second package and is not electrically connected to a second lead formed in a second region outside the first region in the intermediate lead frame needs to be electrically connected to the second lead, based on specifications of a first chip used in the first package and a second chip used in the second package; and
deforming the planar shape of the intermediate lead frame such that the first lead determined to need to be electrically connected to the second lead is electrically connected to the second lead and that the first lead determined not to need to be electrically connected to the second lead is deleted so as to form a planar shape of a common lead frame that can be used for both the first package and the second package.

(Supplementary Note 8)

The control program according to supplementary note 7,
further causing the computer to execute processing of making a thickness of at least a part of a lead portion through which any one of the first cutting line and the second cutting line passes smaller than a thickness of a lead portion through which the first cutting line and the second cutting line do not pass in the intermediate lead frame.

(Supplementary Note 9)

The control program according to supplementary note 7,
further causing the computer to execute processing of forming a through hole in at least a part of a lead portion through which any one of the first cutting line and the second cutting line passes in the intermediate lead frame.

What is claimed is:

1. A common lead frame that can be used for both a first package and a second package, the common lead frame having a planar shape according to specifications of each of a first chip used in the first package and a second chip used in the second package,
wherein a thickness of at least a part of a lead portion through which any one of a first cutting line corresponding to an outer peripheral side of the first package and a second cutting line corresponding to an outer peripheral side of the second package passes is smaller than a thickness of a lead portion through which the first cutting line and the second cutting line do not pass.

2. The common lead frame according to claim 1,
wherein a through hole is formed in at least a part of a lead portion through which any one of the first cutting line and the second cutting line passes.

3. A semiconductor device that is either the first package or the second package for which the common lead frame according to claim 1 is used.

4. The common lead frame according to claim 1,
wherein the common lead frame can be used for any of the first package, the second package, and a third package, and has a planar shape according to specifications of a third chip used in the third package in addition to the specifications of the first chip and the second chip, and
wherein a thickness of at least a part of a lead portion through which any one of the first cutting line, the second cutting line, and a third cutting line corresponding to an outer peripheral side of the third package passes is smaller than a thickness of a lead portion through which the first cutting line, the second cutting line, and the third cutting line do not pass.

5. The common lead frame according to claim 4,
wherein a through hole is formed in at least a part of a lead portion through which any one of the first cutting line, the second cutting line, and the third cutting line passes.

6. A semiconductor device that is any one of the first package, the second package, and the third package for which the common lead frame according to claim 4 is used.

7. A method for forming a common lead frame, the method comprising causing a computer to:
form a planar shape of a common lead frame that can be used for both a first package and a second package, based on specifications of each of a first chip used in the first package and a second chip used in the second package; and
make a thickness of at least a part of a lead portion through which any one of a first cutting line corresponding to an outer peripheral side of the first package and a second cutting line corresponding to an outer peripheral side of the second package passes smaller than a thickness of a lead portion through which the first cutting line and the second cutting line do not pass in the common lead frame.

8. The method for forming a common lead frame according to claim 7, the method comprising:
forming a through hole in at least a part of a lead portion through which any one of the first cutting line and the second cutting line passes in the common lead frame.

9. The method for forming a common lead frame according to claim 7, the method comprising:
forming a planar shape of a common lead frame that can be used for any of the first package, the second package, and a third package, based on specifications of a third chip used in the third package in addition to the specifications of each of the first chip and the second chip; and
making a thickness of at least a part of a lead portion through which any one of the first cutting line, the second cutting line, and a third cutting line corresponding to an outer peripheral side of the third package passes smaller than a thickness of a lead portion through which the first cutting line, the second cutting line, and the third cutting line do not pass in the common lead frame.

10. The method for forming a common lead frame according to claim 9, the method comprising:
forming a through hole in at least a part of a lead portion through which any one of the first cutting line and the second cutting line passes in the common lead frame.

11. A control program for causing a computer to execute processing of:
forming a planar shape of a common lead frame that can be used for both a first package and a second package, based on specifications of each of a first chip used in the first package and a second chip used in the second package; and
making a thickness of at least a part of a lead portion through which any one of a first cutting line corresponding to an outer peripheral side of the first package and a second cutting line corresponding to an outer peripheral side of the second package passes smaller than a thickness of a lead portion through which the first cutting line and the second cutting line do not pass in the common lead frame.

12. The control program according to claim 11,
further causing the computer to execute processing of forming a through hole in at least a part of a lead portion through which any one of the first cutting line and the second cutting line passes in the common lead frame.

13. The control program according to claim 11,
wherein a planar shape of a common lead frame that can be used for any of the first package, the second package, and a third package is formed based on specifications of a third chip used in the third package in addition to the specifications of each of the first chip and the second chip in the processing of forming the planar shape of the common lead frame, and
wherein a thickness of at least a part of a lead portion through which any one of the first cutting line, the second cutting line, and a third cutting line corresponding to an outer peripheral side of the third package passes is made smaller than a thickness of a lead portion through which the first cutting line, the second cutting line, and the third cutting line do not pass in the common lead frame in the processing of making the thickness of the lead portion smaller.

14. The control program according to claim 13,
further causing the computer to execute processing of forming a through hole in at least a part of a lead portion through which any one of the first cutting line and the second cutting line passes in the common lead frame.
